(19) United States
(12) Patent Application Publication
(10) Pub. No.: US 2004/0059985 A1
(43) Pub. Date: Mar. 25, 2004

(54) Method and apparatus for tracking address of memory errors

(76) Inventor: Guy BL Sharp, Carlsbad, CA (US)

Correspondence Address: B. Noel Kivlin, Conley, Rose, & Tayon, P.C., P.O. Box 398, Austin, TX, 78767, US

(21) Appl. No.: 10/254,169

(22) Filed: Sep. 25, 2002

(51) Int. Cl. G11C 29/00

(52) U.S. Cl. 714/763

(57) ABSTRACT

A method and apparatus for tracking an address of a memory error. In one embodiment, a memory controller of a memory subsystem may convey an address to a memory via an address bus. The address may be received by both the memory and an address latch coupled to the memory bus. Data may be read from the memory responsive to its receiving the address. The memory controller may include an error correction subsystem which checks the data read from the memory address for errors. If the error correction subsystem detects an error in the data read from memory, it may assert a latch inhibit signal. The address latch may inhibit updating of the stored address for subsequent memory accesses responsive to receiving the latch inhibit signal. The stored address may be read from the address latch via a serial bus to either the memory controller or a service processor.

### BACKGROUND OF THE INVENTION

1. Field of the Invention

This invention relates to computer system memory, and more particularly, to tracking errors occurring in a memory.

2. Description of the Related Art

Computer systems typically use various error correction mechanisms in order to correct errors that occur in memory subsystems. Such errors may occur in the reading of data from a main system memory, which may include one or more banks of DRAM (dynamic random access memory). These memory banks may include one or more modules upon which DRAM chips are implemented. Although random errors may sometimes occur in one or more of these DRAM chips, error correction mechanisms may ensure reliable system operation despite these errors. Error correction mechanisms may be especially critical with the use of DRAM, as DRAM chips may be more prone to error than various other types of memory chips.

Despite the ability of error correction mechanisms to correct errors in data read from memory, it may be desirable in some instances to replace the part or parts where these errors occur. A memory address may be required in order to pinpoint the location of an error's origin. This may not be possible with typical memory subsystems, which may issue an address for a read command, but do not retain the address. Thus, ascertaining a faulty memory location may be a trial and error process which can be time consuming. The lost time in locating and replacing faulty memory parts may reduce the availability of a computer system, and may also result in greater operating costs.

### SUMMARY OF THE INVENTION

A method and apparatus for tracking an address of a memory error is disclosed. In one embodiment, a memory controller of a memory subsystem may convey an address to a memory via an address bus. The address may be received by both the memory and an address latch coupled to the memory bus. Data may be read from the memory responsive to its receiving the address. The memory controller may include an error detection and correction subsystem which checks the data read from the memory address for errors. If the error detection and correction subsystem detects an error in the data read from memory a latch inhibit signal may be asserted. The address latch may be inhibited from updating the stored address for subsequent memory accesses responsive to receiving the latch inhibit signal. The stored address may be read from the address latch via a serial bus to either the memory controller or a service processor.

### BRIEF DESCRIPTION OF THE DRAWINGS

Other aspects of the invention will become apparent upon reading the following detailed description and upon reference to the accompanying drawings in which:

FIG. 1 is a block diagram of one embodiment of a computer system including a memory subsystem;

FIG. 2 is a block diagram of one embodiment of a memory subsystem including an address latch;

FIG. 3 is a block diagram of an alternate embodiment of a memory subsystem including an address latch; and

FIG. 4 is a flow diagram of a method for inhibiting the updating of an address latch.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

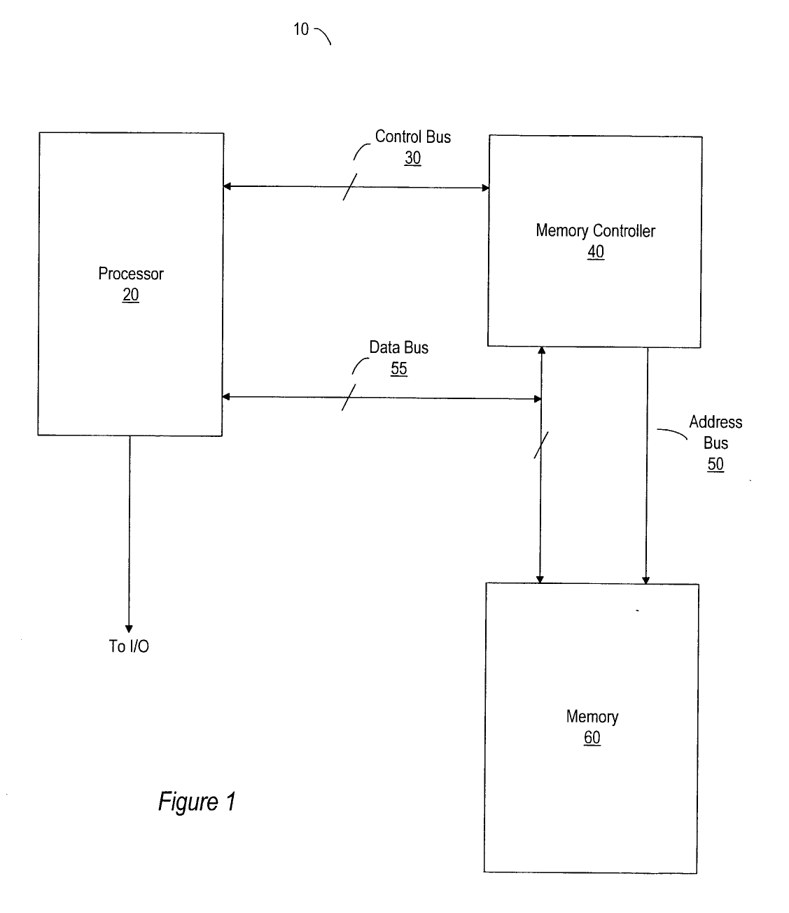

Turning now to FIG. 1, a block diagram of one embodiment of a computer system including a memory subsystem is shown. Computer system 10 includes processor 20, memory controller 40, and memory 80. Processor 20 may be any type of general purpose processor, or may be a special purpose processor in certain types of computer systems (e.g. digital signal processing systems). It should also be noted that embodiments of computer system 10 including multiple processor are possible and contemplated.

Processor 20 may be coupled to memory controller 40 by control bus 30 and data bus 55. Control signals may be conveyed from processor 20 to memory controller 40 over control bus 30. These controls signals may include signals indicating a request for a memory access by processor 20 Data bus 55 may couple processor 20 to both memory controller 40 and memory 60. During a memory read access, data may be conveyed from memory 60 to processor 20 over data bus 55.

Memory controller 40 may be coupled to memory 60 by both data bus 55 and address bus 50. During a memory read or write cycle, memory controller 40 may convey address signals to memory 60 via the address bus. In one embodiment, memory 60 may require both a row and a column address, and thus memory controller 40 may be configured to convey both of these addresses. During a memory read cycle, both processor 20 and memory controller 40 may receive data signals conveyed on data bus 55.

Memory 60 may be one or more of several different types of memory. In one embodiment, memory 60 may be dynamic random access memory (DRAM). Memory 60 may be implemented in DRAM chips mounted to memory modules that may be inserted into memory sockets on a system board. In other embodiments, memory 60 may be implemented as DRAM chips mounted directly to the system board. Embodiments implementing a combination of directly mounted DRAM chips and memory modules mounted in sockets are also possible and contemplated. It should be noted that memories implementing other technologies besides DRAM are also possible and contemplated.

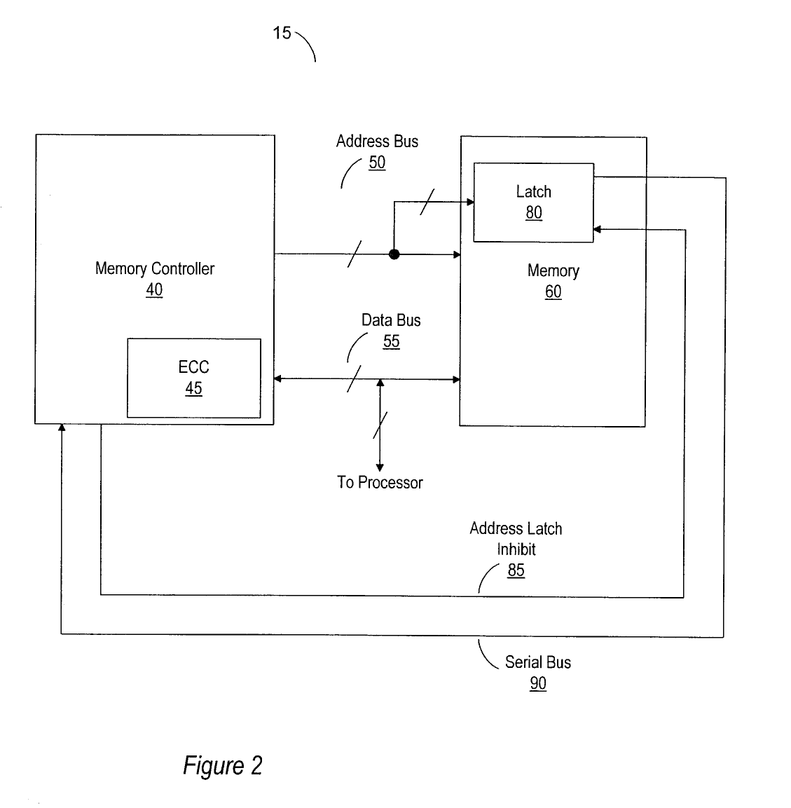

Moving now to FIG. 2, a block diagram of one embodiment of a memory subsystem including an address latch is shown. In the embodiment shown, memory subsystem includes memory controller 40 which is coupled to memory 60 by both address bus 50 and data bus 55. Other signal connections (not shown here) may also be present, including connections for a write enable signal, a read enable signal, a row address strobe signal, and a column address strobe signal. As noted above, memory 60 may be implemented in various embodiments as DRAM chips which may be mounted upon memory modules, a system board, or both.

Memory controller 40 may include an error detection and correction subsystem 45. During a read cycle, error correction and detection subsystem 45 may receive data from memory 60 via data bus 55. Error detection and correction subsystem 45 may perform a check of the data read from memory in order to determine if any errors are present. In one embodiment, each block of data read from memory 60 may include one or more check bits. Error detection and correction subsystem 45 may perform error checks using these check bits and the data within the data block to determine whether the correct number of logic l's or logic 0's are present within the given data block. Error detection and correction subsystem 45 may use a generated code from the data when making these checks. If an error is detected by error detection and correction subsystem 45, it may alter the logic state of the bit in error in order to return the data block to its correct value.

Other embodiments of error detection and correction subsystem 45 may be implemented using various error detection and correction schemes.

Memory 60, as noted above, may be one of several different types of memory, including DRAM, and may be implemented using memory modules, DRAM chips mounted to a system board, or both. In the embodiment shown, memory 60 includes at least one address latch 80. Embodiments having multiple instances of address latch 80 are possible and contemplated. In some embodiments, an address latch 80 may be present on one or more memory modules. In other embodiments, an address latch may be implemented on one or more memory chips mounted to either a memory module or system board. Embodiments are also possible and contemplated where address latch is implemented on a system board separate from either memory modules or memory chips.

Address latch 80 may be coupled to address bus 50, and may be configured to store a received memory address during a memory read cycle. Address latch 80 may include storage for both a row address and column address in embodiments in which the memory requires both row and column addresses.

During a read cycle, memory controller 40 may convey a memory address to both memory 60 and address latch 80. The memory may access the contents of the memory at the specified address, while address latch 80 may store the specified address. The data read from memory 60 may be conveyed to error detection and correction subsystem 45 of memory controller 40, as well as to a processor and/or other destination. Error detection and correction subsystem 45 may perform error-checking functions on each block of data read from memory 60, as described above. If an error is detected, memory controller 40 may respond by asserting an address latch inhibit signal on signal line 85. When received by address latch 80, the address latch inhibit signal may prevent updates to address latch 80 during subsequent reads of memory 60. Address latch 80 may continue to store the address corresponding to the detected error during subsequent reads of memory 60.

In the embodiment shown, address latch 80 may be coupled to serial bus 90, which may also be coupled to memory controller 40. In one embodiment, serial bus 90 may be an I²C (inter-integrated circuit) bus, although embodiments implementing other types of serial buses are possible and contemplated. Subsequent to the detection of an error and assertion of the latch inhibit signal, memory controller 40 may read the retained memory address stored in address latch 80. The address read from address latch 80 may then be available for observation through a computer system output means thereby providing information ascertaining the location of the error. Memory controller 40 may also de-assert the latch inhibit signal responsive to reading the address through serial bus 90, thereby allowing updates of the address to be stored in address latch 80 during subsequent memory read cycles.

In some computer systems designed for a high memory access bandwidth, it may not be possible for error detection and correction subsystem 45 to determine whether errors are present in a given data block before memory controller 40 issues another address. In such embodiments, address latch 80 may be configured to store multiple addresses in order to ensure the address corresponding to a block of data read from memory is retained. Address latch 40 may still be configured to be inhibited if an error is detected in order to prevent further updates, thereby ensuring retention of the address corresponding to the erroneous data block.

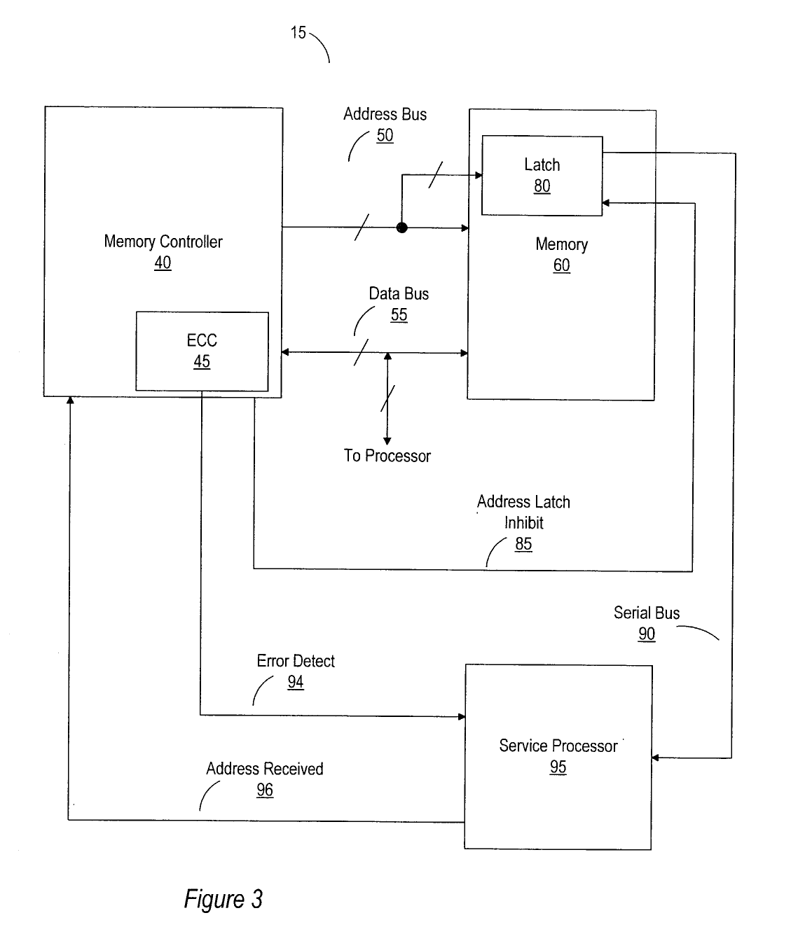

FIG. 3 is a block diagram of an alternate embodiment of a memory subsystem including an address latch. In the embodiment shown, memory subsystem includes memory controller 40 having error detection and correction subsystem 45, and memory 60 including address latch 80. Also included in this embodiment is service processor 95, which may be coupled to address latch 80. Service processor may be configured to receive the address read from address latch 80 via the serial bus in this embodiment. Error detection and correction subsystem 45 may be configured to assert an error detect signal upon detecting an error in a data block read from memory 60. The error detect signal may be conveyed to service processor 95 via signal line 94. Responsive to receiving the error detect signal, service processor 95 may serially access the address retained in address latch 80 using serial bus 90. When the full address has been received, service processor 95 may convey an address received signal to memory controller 40. Memory controller 40 may respond to the address received signal by de-asserting the latch inhibit signal, thereby allowing updates to address latch 80 during subsequent memory read cycles. Service processor 95 may also be configured to convey the address corresponding to an error to a computer system output.

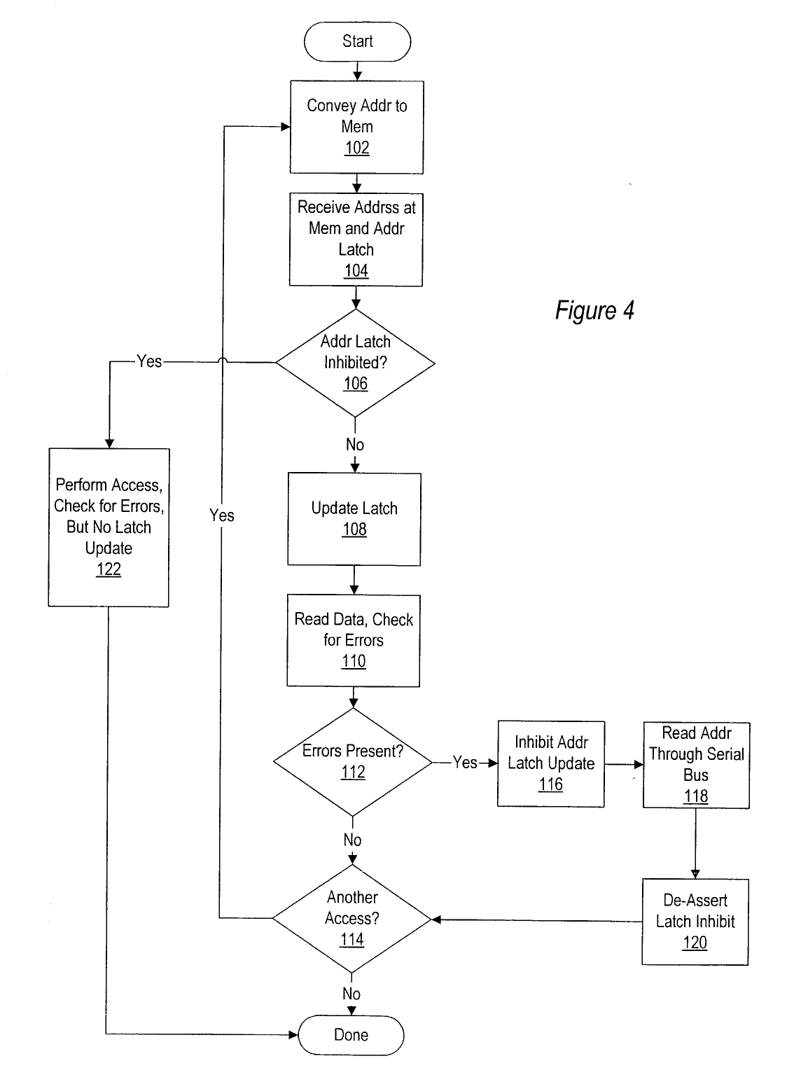

Turning now to FIG. 4, a flow diagram of a method for inhibiting the updating of an address latch is shown. Method 100 may begin with a memory controller conveying an address to a memory during a memory read cycle (item 102). The address may be received by both the memory and an address latch associated with the memory (item 104). The address latch may be configured to receive an address latch inhibit signal, which may prevent the received address from being stored. Logic in the address latch may detect whether the address latch inhibit signal is asserted (item 106). If the address latch inhibit signal is not asserted, then the address latch may be updated to store the received address. If the address latch inhibit signal is asserted, the memory access may still be performed, the address latch may be prevented from being updated (item 122). Error checking may still be performed by an error detection and correction subsystem, but since the address latch is inhibited, the address of any errors may not be retained.

Data may be read from the memory at the specified address responsive to the receiving of the memory address by the memory (item 110). Responsive to the memory access, data corresponding to the specified address may be received by an error correction subsystem. The error detection and correction subsystem may perform a checking routine to determine the presence of any errors (item 112). If no errors are present, a determination may be made as to whether additional memory accesses are to be made (item 114). If additional memory accesses are requested, another address may be conveyed to memory (item 102).

If the error detection and correction subsystem determines that errors are present in the data at the accessed address, the memory controller may assert an address latch inhibit signal. Assertion of the address latch inhibit signal may prevent further updates to the address latch while retaining the address corresponding to the data block that is in error (item 116). Responsive to the inhibiting of the address latch from further updates, the stored address may be serially read from the address latch (item 118). It should be noted that other embodiments are possible and contemplated wherein the address may be read in parallel from the address latch. The address may be read by the memory controller or a service processor coupled to the address latch. Responsive to completing the read of the address from the address latch, the address latch inhibit signal may be de-asserted. De-assertion of the address latch inhibit signal may allow the address latch to be updated with an address of a next memory access. A determination may also be made as to whether additional memory accesses are to be performed (item 114). If no further memory accesses are necessary at the given time, then the method may be complete until restarted by another memory access request. If another memory access is to be made at the time of the determination, a memory address corresponding to the data to be read may be conveyed to the memory.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A method comprising:
a memory controller conveying an address to a memory via a memory bus;
receiving the memory address in the memory and in an address latch; the address latch coupled to the memory bus;
reading data from the memory responsive to the memory receiving the address;
detecting an error in the data read from the memory; and
inhibiting updates of the address latch responsive to detecting the error.

2. The method as recited in claim 1 further comprising the memory controller asserting a latch inhibit signal responsive to detecting the error, wherein the address latch is configured to perform said inhibiting responsive to receiving the latch inhibit signal.

3. The method as recited in claim 1 further comprising reading the memory address from the address latch through a serial bus.

4. The method as recited in claim 3, wherein the serial bus is an I²C bus.

5. The method as recited in claim 3, wherein the serial bus is coupled to the memory controller.

6. The method as recited in claim 3, wherein the serial bus is coupled to a service processor.

7. The method as recited in claim 1, wherein the memory is dynamic random access memory (DRAM).

8. The method as recited in claim 7, wherein the address latch is located on a DRAM chip.

9. The method as recited in claim 1, wherein the memory address includes a row address and a column address, and wherein the address latch is configured to store both the row address and the column address.

10. The method as recited in claim 1, wherein the address latch is located on a memory module.

11. The method as recited in claim 1, wherein the address latch is configured to store multiple memory addresses.

12. A memory subsystem comprising:
a memory controller;
a memory coupled to receive an address from the memory controller via an address bus;
an address latch coupled to receive the address from the memory controller, wherein the address latch is further coupled to receive a latch inhibit signal responsive to a detection of an error in data read from the memory address, wherein receiving the latch inhibit signal prevents further updates to the address latch.

13. The memory subsystem as recited in claim 12, wherein the memory controller includes an error detection and correction subsystem, and wherein the memory controller is configured to assert the latch inhibit signal responsive to the error detection and correction subsystem detecting the error.

14. The memory subsystem as recited in claim 12, wherein the memory subsystem includes a serial bus coupled to the address latch.

15. The memory subsystem as recited in claim 14, wherein the serial bus is an I²C bus.

16. The memory subsystem as recited in claim 14, wherein the serial bus is coupled to the memory controller, and wherein the memory controller is configured to read the address stored in the address latch via the serial bus.

17. The memory subsystem as recited in claim 14, wherein a service processor is coupled to the serial bus, wherein the service processor is configured to read the address stored in the address latch via the serial bus.

18. The memory subsystem as recited in claim 12, wherein the memory is dynamic random access memory (DRAM).

19. The memory subsystem as recited in claim 18, wherein the address latch is located on a DRAM chip.

20. The memory subsystem as recited in claim 12, wherein the memory address includes a row address and a column address, and wherein the address latch is configured to store both the row address and the column address.

21. The memory subsystem as recited in claim 12, wherein the address latch is located on a memory module.

22. The memory subsystem as recited in claim 12, wherein the address latch is configured to store multiple memory addresses.
